(19) United States
(12) Patent Application Publication
(10) Pub. No.: US 2005/0147780 A1
(43) Pub. Date: Jul. 7, 2005

(54) Porous electroconductive material having light transmitting property

(76) Inventors: Tetsuro Jin, Osaka (JP); Hong Lin, Osaka (JP); Tetsuo Yazawa, Osaka (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/509,794

(22) PCT Filed: Apr. 2, 2003
(86) PCT No.: PCT/JP03/04205

(30) Foreign Application Priority Data
Apr. 2, 2002 (JP) 2002-100661

(51) Int. Cl. B44F 1/06

(52) U.S. Cl. 428/38

(57) ABSTRACT

A porous electroconductive material having light transmitting property which comprises a porous glass and, formed on the outer surface thereof and also on the surface inside fine pores thereof, an electroconductive oxide film; and a method for preparing the porous electroconductive material which comprises using the chemical vapor transporting method, the sputtering method, the impregnation method, a method wherein a silanol group present on the surface of the porous glass is reacted with an organic metal compound and the product is oxidized by heating in air, or a method wherein a mixture of a polymer compound or an amine group-containing organic metal compound with a raw material for a film is applied to a substrate and then the polymer compound or the organic component is burned and removed.

### FIELD OF THE INVENTION

The present invention relates to a porous conductive material having light transmitting property which is useful, e.g., as a material for electrodes in a Graetzel type solar cell, or as a material for electrodes in a photomultiplier or electroluminescent element.

### BACKGROUND ART

Generally, conventional conductive materials having light transmitting property comprise tin oxide, indium oxide, a composite oxide thereof (ITO), or like electron-conductive oxides applied to a surface of a quartz glass plate or like glass plates by vapor deposition or sputtering. However, these conductive materials can not be made porous and are limited to use as a flat article.

Meanwhile, sintered stainless steel filters are known as porous conductive filters. The filter, however, has no light transmitting properties. While attempts have been made to produce a porous substrate by pressing together fine particles of ITO or SnO₂, these have produced white sintered product, failing to impart light transmitting properties to the product (e.g., N. Ulagappan and C. N. R. Rao, J. Chem. Soc., Chem. Commun., 1996, 168. and G. J. Li and S. Kawi, Talanta, 1998, 45, 759.).

Conductive materials prepared by the use of porous glass have been previously reported, but only their outer surfaces are conductive (e.g., J. Dong and H. D. Gafney, J. Non-Crystalline Solids, 1996, 203, 329-333). Porous materials which are conductive in their entirety have not been heretofore produced.

### DISCLOSURE OF THE INVENTION

The inventors of the invention found that a porous conductive material having porosity, conductivity, and light transmitting properties can be produced by forming a conductive oxide film on the surfaces inside pores of the porous glass and on the outer surfaces thereof. Based on this finding, the inventor completed the invention.

The invention provides the following.
1. A light transmitting porous conductive material comprising a porous glass and a conductive oxide film formed on the outer surfaces of the porous glass and on the surfaces inside the pores thereof.
2. The porous conductive material according to item 1, wherein the resistivity of an outer surface of the porous conductive material is 10⁻⁴ to 10⁴ Ω·cm, the resistance between the two outer surfaces of the porous conductive material is 10⁻⁴ k to 500 kΩ, and the specific surface area of the porous conductive material is 4 to 600 m²/g.
3. The porous conductive material according to item 2, wherein the resistivity of an outer surface of the porous conductive material is 10⁻⁴ to 10¹ Ω·cm, the resistance between the two outer surfaces of the porous conductive material is 10⁻⁴ k to 300 kΩ, and the specific surface area of the porous conductive material is 9 to 400 m²/g.
4. The porous conductive material according to item 1, wherein the conductive oxide film is constituted by at least one conductive oxids selected from the group consisting of SnO₂, In₂O₃, ITO (Sn doped In₂O₃), ZnO, PbO₂, ZnSb₂O₆, CdO, CdIn₂O₄, MgIn₂O₄, ZnGa₂O₄, CdGa₂O₄, Cd₂SnO₄, Zn2SnO₄, Tl₂O₃, TIOF, Ga₂O₃, GaInO₃, Cd₂SnO₄, CdSnO₃, In₂TeO₆, InGaMgO₄, InGaZnO₄, Zn₂In₂O₅, AgSbO₃, Cd₂GeO₄, Cd₂Ge₂O₇, ZnSnO₃, AgInO₂, CuAlO₂, CuGaO₂, SrCu₂O₂, amorphous In₂O₃, amorphous CdO—GeO₂, Sb doped SnO₂, F doped SnO₂, In doped ZnO, Ga doped ZnO and Al doped ZnO.
5. The porous conductive material according to item 4, wherein the conductive oxide film is constituted by at least one conductive oxide selected from the group consisting of SnO₂, In₂O₃, ITO, Sb doped SnO₂ and F doped SnO₂.
6. A Graetzel type solar cell comprising the porous conductive material according to any one of items 1 to 5 as an electrode material.
7. A photomultiplier comprising the porous conductive material according to any one of items 1 to 5 as an electrode material.
8. A method for preparing a light transmitting porous conductive material comprising the steps of: (1) forming a conductive oxide film on the surfaces inside the pores of a porous glass, and (2) forming a conductive oxide film on the outer surfaces of the porous glass.
9. The method according to item 8, wherein any method selected from the group consisting of the following methods (i) to (v) is employed in the step (1) of forming a conductive oxide film on the surfaces inside the pores of the porous glass:(i) a chemical vapor deposition method, (ii) a sputtering method, (iii) an impregnation method, (iv) a method wherein silanol groups present on the surface of the porous glass are reacted with an organic metal compound under high vacuum and the reaction product is then oxidized by heating in air, and (v) a method wherein a mixture of a polymer or an amine group-containing organic metal compound with a raw material for the film is applied to the surface of the porous glass and then the polymer or the organic compound is removed by heating in air.
10. The method according to item 8, wherein any method selected from the group consisting of the following methods (i), (ii) and (v) is employed in the step (2) of forming a conductive oxide film on the outer surfaces of the porous glass: (i) a chemical vapor deposition method, (ii) a sputtering method, and (v) a method wherein a mixture of a polymer or an amine group-containing organic metal compound with a raw material for the film is applied to the surface of the porous glass and then the polymer or the organic compound is removed by heating in air.
11. The method according to item 8, wherein any method selected from the group consisting of the following methods (i), (iv) and (v) is employed in the step (1) of forming a conductive oxide film on the surfaces inside the pores of the porous glass:(i) a chemical vapor deposition method, (iv) a method wherein silanol groups present on the surface of the porous glass are reacted with an organic metal compound under high vacuum and the reaction product is then oxidized by heating in air, and (v) a method wherein a mixture of a polymer or an amine group-containing organic metal compound with a raw material for the film is applied to the surface of the porous glass and then the polymer or the organic compound is removed by heating in air, and wherein the method (i) or (v) is employed in the step (2) of forming a conductive oxide film on the outer surfaces of the porous glass:(i) a chemical vapor deposition method, or (v) a method wherein a mixture of a polymer or an amine group-containing organic metal compound with a raw material for the film is applied to the surface of the porous glass and then the polymer or the organic compound is removed by heating in air.

The invention is described in more detail below.

The invention provides a porous conductive material having light transmitting properties, the material being prepared by forming a conductive oxide film on the surfaces of a porous glass.

The term “having light transmitting properties” used in the invention means having a light transmittance of 35% or more in the wavelength range of 300 to 800 nm.

In the invention, the term “surface resistivity” refers to the resistivity of a conductive oxide film formed on the outer surface of the porous glass.

In the invention, the term “resistance between the two outer surfaces of the porous conductive material” refers to the electrical resistance between the two outer surfaces of the porous material. More specifically, the term means the resistance between the two outer surfaces of the porous material in the case of the porous glass having a thickness of 1 mm.

The outer surface of the porous conductive material according to the invention usually has a resistivity in the range of about 10⁻⁴ to about 10⁴ Ω·cm, and preferably about 10⁻⁴ to about 10¹ Ω·cm.

The resistance between the two outer surfaces of the porous electroconductive material is usually about 10⁴ k to about 500 kΩ, and preferably about 10⁻⁴ k to about 300 kΩ.

The porous conductive material of the invention usually has a specific surface area of about 4 to about 600 m²/g, preferably about 9 to about 400 m²/g.

When the porous conductive material of the invention is used as an electrode material in a solar cell, a photomultiplier or the like in the electricity/electronics field, it is preferable that the resistivity of the outer surface of the porous conductive material is 10⁻⁴ to 10⁴ Ω·cm, the resistance between the two outer surfaces of the porous material is 10⁻⁴ k to 500 kΩ, and the specific surface area of the porous conductive material is 4 to 600 m²/g. Further it is more preferable that the resistivity of the outer surface of the porous material is 10⁻⁴ to 10¹ Ω·cm, the resistance between the two outer surfaces of the porous material is 10⁻⁴ to 100 kΩ, and the specific surface area of the porous material is 9 to 400 m²/g.

Porous Glass

The porous glass referred to in the invention is glass replete with through pores. The porous glass has excellent heat resistance, durability and weathering resistance, and has other properties of typical inorganic films.

The composition of the porous glass is not limited. Examples are silica-based porous glass A (glass composition of base glass: SiO₂(55-80 wt %)-B₂O₃—Na₂O—(Al₂O₃)), silica-based porous glass B (glass composition of base glass: SiO₂(35-55 wt %)-B₂O₃—Na₂O), silica-based porous glass C (glass composition of base glass: SiO₂—B₂O₃—CaO—Al₂O₃), silica-based porous glass D (glass composition of base glass: SiO₂—P₂O₅—Na₂O), silica-based porous glass E (SiO₂—B₂O₃—Na₂O—RO(R=alkaline earth, Zn)), TiO₂-containing porous glass (glass composition of base glass: SiO₂—B₂O₃—CaO—MgO—Al₂O₃—TiO₂ (containing 49.5 mol % or less of TiO₂), and rare earth-containing porous glass (glass composition of base glass: B₂O₃—Na₂O—(CeO₂, ThO₂, HfO₂, La₂O₃)) and so on.

A porous glass having the composition of the silica-based porous glasses A, B or D is preferred because of their high transparency.

The above-mentioned glasses are known to give rise to phase separation with heat treatment to provide two kinds of glass phases different compositions from each other. The second phase produced by phase separation can be dissolved and removed to leave voids, giving a porous glass replete with through pores.

The diameter of the pores in the porous glass to be used in the invention is not limited, but is preferably 1 to 100 nm, and more preferably 4 to 50 nm. The porous glass has a specific surface area of about 4 to about 3400 m²/g, and preferably about 9 to about 900 m²/g. The pore diameter and specific surface area of the porous glass can be adjusted by the heat-treating time and/or temperature.

The shape of the porous glass is not limited, but is preferably in the form of a tube or a flat plate, particularly a flat plate. In the case of a flat plate, its thickness is not limited but, in view of ease of processing, preferably 100 micrometers to several millimeters, and more preferably 0.5 mm to 1 mm.

The surface of the porous glass in the invention is inclusive of not only the outer surfaces of the porous glass but also the surfaces of the internal wall of the pores.

That is, a conductive oxide film of the porous conductive material of the invention is formed so as to cover the outer surfaces of the porous glass and also the surfaces inside the pores thereof.

In view of light transmitting properties and retention of pores in the obtained material, it is desirable to prepare the porous conductive material having a conductive oxide film formed on the outer surfaces of the porous glass and on the surfaces inside the pores thereof by a method comprising the two steps of: (1) forming a conductive oxide film on the surfaces inside the pores of the porous glass, and (2) forming a conductive oxide film on the outer surfaces thereof.

Film of Conductive Oxide

There is no limitation on the conductive oxide for forming a conductive oxide film in the invention insofar as the film formed therefrom is transparent and is electroconductive. Usable as the conductive oxide is, for example, at least one member selected from the group consisting of SnO₂, In₂O₃, ITO (Sn doped In₂O₃), ZnO, PbO₂, ZnSb₂O₆, CdO, CdIn₂O₄, MgIn₂O₄, ZnGa₂O₄, CdGa₂O₄, Cd₂SnO₄, Zn₂SnO₄, Tl₂O₃, TIOF, Ga₂O₃, GaInO₃, Cd₂SnO₄, CdSnO₃, In₂TeO₆, InGaMgO₄, InGaZnO₄, Zn₂In₂O₅, AgSbO₃, Cd₂GeO₄, Cd₂Ge₂O₇, ZnSnO₃, AgInO₂, CuAlO₂, CuGaO₂, SrCu₂O₂, amorphous In₂O₃, amorphous CdO—GeO₂, Sb doped SnO₂, F doped SnO₂, In doped ZnO, Ga doped ZnO and Al doped ZnO.

Among these, SnO₂, In₂O₃, ITO, Sb doped SnO₂, and F doped SnO₂ are desirable in view of transparency and low resistivity.

Incidentally, the term “Sb doped SnO₂” is used to mean SnO₂ containing Sb as a dopant, and likewise the expressions “F doped SnO₂, Ga doped ZnO and Sn doped In₂O₃ (ITO)”.

The thickness of the conductive oxide film on the outer surface of the porous glass is suitably 0.1 to 10 μm. On the surface inside the pores thereof, the thickness of the conductive oxide film is so as not to clog the-pores and suitably at least 0.1 nm and less than 50 nm.

The thickness of the conductive oxide film can be suitably controlled according to the purpose of the porous conductive material. For instance, when the porous material is used as an electrode material, it is preferable that the thickness of the film on the outer surface of the porous glass is 0.5 to 3 μm, and the thickness of the film on the surface inside the pores thereof is at least 1 nm and less than 25 nm, in that remarkable effects can be achieved in Photons-to-Current conversion efficiency and so on.

The conductive oxide film of the outer surface of the porous conductive material as well as of the surface inside the pores thereof need not be continuously formed, and may be partly discontinuous.

Method for Preparing a Porous Conductive Material

The porous conductive material of the invention can be prepared by a method comprising the two steps of: (1) forming a conductive oxide film on the surfaces inside the pores of the porous glass, and (2) forming a conductive oxide film on the outer surfaces of the porous glass.

In steps (1) and (2), the following methods can be used: (i) a chemical vapor deposition method, (ii) a sputtering method, (iii) an impregnation method, (iv) a method wherein silanol groups present on the surface of the porous glass are reacted with an organic metal compound under high vacuum and the reaction product is then oxidized by heating in air, (v) a method wherein a mixture of a polymer or an amine group-containing organic metal compound with a raw material for the film is applied to the surface of the porous glass and then the polymer or the organic compound is removed by heating in air, or like methods.

In the step (1) of forming a conductive oxide film on the surfaces inside the pores of the porous glass, any method selected from the following methods is preferably used: (i) a chemical vapor deposition method, (ii) a sputtering method, (iii) an impregnation method, (iv) a method wherein silanol groups present on the surface of the porous glass are reacted with an organic metal compound under high vacuum and the reaction product is then oxidized by heating in air, and (v) a method wherein a mixture of a polymer or an amine group-containing organic metal compound with a raw material for the film is applied to the surface of the porous glass and then the polymer compound or the organic compound is removed by heating in air.

In the step (2) of forming a conductive oxide film on the outer surfaces of the porous glass, any method selected from the following methods is preferably employed; (i) a chemical vapor deposition method, (ii) a sputtering method, and (v) a method wherein a mixture of a polymer compound or an amine group-containing organic metal compound with a raw material for the film is applied to the surface of the porous glass and then the polymer or the organic compound is removed by heating in air.

The methods (i) to (v) are described below in greater detail.

(i) Chemical Vapor Deposition Method

The chemical vapor deposition method is the same kind of method as the conventional chemical vapor deposition methods i.e. so-called CVD. In this method, a raw material gas is transported to a heated substrate together with a carrier gas or a reactive gas, so that a reaction product made by the chemical reaction is deposited on the substrate to form a film. Examples of reactors that can be used include the device shown in FIG. 1.

Examples of raw material for the conductive oxide film are chlorides, alkoxides, reactive organic metal compounds, etc. that contain a metal atom constituting the conductive film. Water, oxygen and/or air may be used together with the raw material for the film when so required, since the contemplated conductive oxide is produced by hydrolysis with water, oxidation reaction with oxygen and/or decomposition by heating. A carrier gas is used to introduce the raw material for the film into a reaction chamber. The carrier gas is not limited insofar as it is a dried gas containing no water and non-reactive. Suitable examples of carrier gas are argon, nitrogen, helium and the like. When water for hydrolysis is introduced into the reaction system, it is possible to use any gas useful as a carrier gas for the raw material for the film. Oxygen and air are also usable.

The amounts of the raw material for the film and water are determinable based on the vapor pressure of the raw material and the mole ratio of water relative to the raw material, and can be suitably adjusted according to the flow rate of carrier gas and the like. The temperatures of the raw material and water can be controlled by dry ice, iced water or a thermostat bath.

In forming the film, the distance between the substrate (porous glass) and the forward end of the nozzle for introduction of the raw material into the reaction chamber is adjusted to about 1 to about 30 mm.

The temperature of the porous glass is adjusted to within the range from room temperature to 800° C., and preferably 300 to 600° C. The reaction time is controlled to within the range from 10 minutes to 100 hours, preferably 0.5 to 10 hours.

When a conductive film is formed on the surface inside the pores of the porous glass, the pressure is reduced on one side of the porous glass while the raw material for the film (water, oxygen and/or air, when required) is introduced from the other side. In this case, the raw material for the film is introduced deep into the through pores of the porous glass due to the difference in the pressure between the two sides to apply a conductive film on the internal surfaces of the pores in the porous glass. The reduction of pressure can be adjusted by a rotary pump or the like. The degree of vacuum can be controlled by a pressure controller. The range of reduced pressure is in the range from 10⁻³ mm Hg to somewhat lower than the atmospheric pressure. After reaction is conducted under reduced pressure on one side, the porous glass may be turned over and reaction may be conducted again.

When a conductive film is formed on the outer surfaces of the porous glass, a reaction is performed under atmospheric pressure without reducing the pressure, and a conductive film is formed on the outer surface of the porous glass. A conductive film may be formed on each side sequentially, or reaction may be made on both sides simultaneously to form the film at one time.

(ii) Sputtering Method

The sputtering method comprises forming a film by glow discharges of a noble gas. In the glow discharge, a noble gas is kept at a pressure of 0.1 to 10 Pa and is caused to eject atoms which pile up on a substrate. An argon gas is frequently used as the noble gas. Specific examples of the sputtering method include DC bipolar sputtering, high frequency sputtering, chemical conversion sputtering, ion beam sputtering, magnetron sputtering, etc.

The contemplated oxide is used as a target for sputtering. The distance from the target to the porous glass is adjusted to 100 to 300 mm.

The temperature of the porous glass is adjusted to within the range from room temperature to 800° C., and preferably 300 to 600° C. The reaction time is adjusted to within the range from 10 minutes to 100 hours, and preferably 0.5 to 10 hours.

When a conductive film is formed on the surface inside the pores of the porous glass, the pressure is reduced on one side of the porous glass while the raw material for the film (along with water, oxygen and/or air, when required) is introduced from the other side. In this case, the raw material for the film is introduced deep into the through pores of the porous glass due to the difference in the pressure between the two sides to apply a conductive film on the internal surfaces of the pores in the porous glass. The reduction of pressure can be adjusted by a rotary pump or the like. The degree of vacuum can be controlled by a pressure controller. The range of the reduced pressure is between 10⁻³ mm Hg and a pressure somewhat lower than the atmospheric pressure.

When a porous glass plate is used as a substrate, the pressure is reduced on one side to conduct a reaction, and the porous glass may then be turned over to carry out a reaction on the other side.

When a conductive film is formed on an outer surface of the porous glass, a reaction may be performed under atmospheric pressure without reducing the pressure to form a conductive film on the outer surface of the porous glass.

(iii) Impregnation Method

The impregnation method comprises immersing a porous glass substrate in a solution containing chloride, alkoxide, reactive organic metal compound or the like that contains a metal atom constituting the conductive film to impregnate the porous glass substrate with the solution; removing air from the pores by reducing the pressure and soaking completely the substrate in the solution to modify the surface of the porous glass substrate, and thermally oxidizing the substrate in the presence of oxygen, whereby a conductive film is formed.

The pressure is generally reduced by a rotary pump. The degree of vacuum can be controlled by a pressure controller. The range of reduced pressure is in the range of from 10⁻¹ mm Hg to somewhat lower than the atmospheric pressure. The impregnation time is adjusted to within the range of from 1 hour to 10 days. The oxidation is conducted in air by heating at a temperature of 300 to 600° C. for 10 minutes to 24 hours.

(iv) Method Wherein Silanol Groups Present on the Surface of the Porous Glass are Reacted with an Organic Metal Compound and the Reaction Product is then Oxidized by Heating in Air (High-vacuum Organic Metal Supporting Method)

The method, wherein silanol groups present on the surface of the porous glass are reacted with an organic metal compound under high vacuum and the reaction product is then oxidized by heating in air, comprises introducing a vapor of a reactive organic metal compound, such as a silane coupling agent, containing a small amount of a metal atom constituting the conductive film to a porous glass under high vacuum to apply the reaction product to the surface of the porous glass, repeating the operation one or a plurarity of times and then conducting thermal oxidation in the presence of oxygen to provide a conductive film. As illustrated in FIG. 2, a reaction chamber is brought to high vacuum. An organic metal compound of a high reactivity placed in a raw material chamber is introduced into the reaction chamber by manipulating a valve to bring the chamber to a suitable pressure, whereby a monomolecular layer of the raw material is formed on the surface of the porous glass substrate (outer surfaces and/or surfaces inside the pores). For example, when a film of SnO₂ is formed, an organic metal compound is introduced with examples of the compound being tin tetrachloride, methyltin trichloride, dimethyltin dichloride, trimethyltin chloride and tetramethyltin. After the operation is repeated one time or a plurality of times, the reaction product is heat-treated at a temperature of 300 to 600° C. in air, thereby providing a transparent porous conductive material having a suitable transparency, a proper electronic conductivity and a controlled surface area.

The term “under high vacuum” used herein means a state under a pressure ranging from about 10⁻⁵ mm Hg to about 10⁻¹ mm Hg. The organic metal compound can be suitably selected according to the composition of the inorganic oxide film to be formed, and includes proper combinations of compounds wherein, e.g., alkyl group, halogen atom, alkoxide group or their suitable combinations is/are bonded to a constituent metal atom.

(v) A Method Wherein a Mixture of a Polymer or an Amine Group-containing Organic Metal Compound with a Raw Material for the Film is Applied to the Surface of the Porous Glass and then the Polymer Compound or the Organic Compound is Removed by Heating in Air (Organic Template Method)

The method, wherein a mixture of a polymer or an amine group-containing organic metal compound with a raw material for the film is applied to the surface of the porous glass and then the polymer or the organic compound is removed by heating in air, comprises adding a polymer or an amine group-containing organic metal compound to a raw material containing a metal atom constituting the conductive film, applying the mixture to a porous glass to form a film, and conducting heat-treatment under an atmosphere containing oxygen to remove by heating the polymer and the organic compound, whereby a porous conductive film is produced. For example, a polymer or an amine group-containing organic metal compound is mixed with a raw material for a film. Thereafter, the mixture is heated in air at a temperature of 30 to 120° C., whereby the amount of the mixture is reduced by about 30%. The mixture is then applied to the surface of the porous glass substrate by a coating method such as dip coating, spin coating, bar coating, doctor blade coating or spray coating. Alternatively the mixture may be applied to the surface of the porous glass by immersing the porous glass in a solution containing a polymer or an amine group-containing organic metal compound.

When the polymer or amine group-containing organic metal compound is removed by heating in air, voids are created in the places previously occupied by the polymer or amine group-containing organic metal compound, while a conductive oxide film is formed elsewhere. Heating is conducted in an electric furnace at a temperature of 300° C. or higher.

The raw material for a film refers to a raw material used for forming a conductive oxide film. Examples of the raw material for a film include a metal-containing compound such as an organic metal compound, metal chloride, metal hydroxide, metal alcoxide, metal oxide and mixtures thereof which can be converted to a conductive oxide by oxidation.

Examples of the polymer are cellulose, polyethylene glycol, polydimethyl siloxane, polyvinyl alcohol, polyvinyl pyrrolidone and derivatives thereof, and the like. Examples of the amine group-containing organic metal compound include amines having a straight chain alkyl group containing 2 to 22 carbon atoms and the like. Amines of various molecular diameters can be used.

The polymer or amine group-containing organic metal compounds exemplified above can be used singly or in combination.

The amount of polymer compound or the amine group-containing organic metal compound to be used is 0.01 to 10 moles, and preferably 0.05 to 2 moles, per mole of the raw material for a film.

In the preparation of the porous conductive material of the invention, a suitable combination of methods can be employed as selected from the above-mentioned methods (i) to (v) in the steps of: (1) forming a conductive oxide film on the surfaces inside the pores of the porous glass, and (2) forming a conductive oxide film on the outer surfaces of the porous glass.

For example, (i) a chemical vapor deposition method can be used in both of the steps of: (1) forming a conductive oxide film on the surfaces inside the pores of porous glass, and (2) forming a conductive oxide film on the outer surfaces of the porous glass.

It is also possible to employ (i) a chemical vapor deposition method in the step (1) of forming a conductive oxide film on the surfaces inside the pores of the porous glass, while employing (v) the method wherein a mixture of a polymer or an amine group-containing organic metal compound with a raw material for the film is applied to the surface of the porous glass and then the polymer or the organic compound is removed by heating in air in the step (2) of forming a conductive oxide film on the outer surfaces of the porous glass.

It is further possible to employ (v) the method wherein a mixture of a polymer or an amine group-containing organic metal compound with a raw material for the film is applied to the surface of the porous glass and then the polymer or the organic compound is removed by heating in air in the step (1) of forming a conductive oxide film on the surfaces inside the pores of the porous glass, while employing (v) the method wherein a mixture of a polymer or an amine group-containing organic metal compound with a raw material for the film is applied to the surface of the porous glass and then the polymer compound or the organic compound is removed by heating in the air in the step (2) of forming a conductive oxide film on the outer surfaces of the porous glass.

It is also possible to employ (iv) the method wherein silanol groups present on the surface of the porous glass are reacted with an organic metal compound and the reaction product is oxidized by heating in air (high vacuum organic metal supporting method) in the step (1) of forming a conductive oxide film on the surfaces inside the pores of the porous glass, while employing (i) a chemical vapor deposition method in the step (2) of forming a conductive oxide film on the outer surfaces of the porous glass.

Use of the Porous Conductive Material

As described above, the porous conductive material of this invention is light transmitting and conductive, and by controlling the pore diameter of the material, its surface area can be increased 1,000 to 100,000 times. Since a conductive film is formed on the surfaces inside the pores of the conductive material, electric current can pass between the film formed on both sides of the material. Further the material can be produced in any form.

Because of these properties, the porous conductive material of the invention is useful as a material for electrodes in a wide variety of devices in the electricity/electronics field. Examples of such devices are optical sensors (photomultipliers), optical secondary batteries, dye-sensitizing solar cells (Graetzel type solar cells), electroluminescence (EL) devices, electrochromism (EC) devices and so on.

For example, a Graetzel type solar cell comprises a dye on a TiO₂ film supported on a transparent conductive film. The dye absorbs the sunlight to cause to charge separation, thereby providing a solar cell. The greater the surface area of TiO₂ film, the greater the amount of dye to be supported, and the higher the efficiency of conversion from light to electricity. When the porous conductive material of the invention is used as the electrode material in a Graetzel type solar cell, the surface area can be increased by several thousands times or more. This means that a cell capable of efficiently converting light energy to electrical energy can be provided.

A photomultiplier comprises a cathode having a material capable of converting light into electron (Photons-to-Current conversion material), a focusing electrode, an electron multiplier and an anode capable of collecting electrons. The greater the surface area of the cathode, the greater the amount of Photons-to-Current conversion material to be supported. When the porous conductive material of the invention is used as the electrode material in a photomultiplier, by introducing the compound capable of converting photons to electrons into the pores of the porous conductive material, the probability of photons colliding with the Photons-to-Current conversion material can be markedly increased. When the porous conductive material of the invention is used as an electrode material in a photomultiplier, the resulting photomultiplier can obtain signals which are at least dozens of times grater than the signals given by a multiplier of a type permitting photons to transmit therethrough.

As described above, when the porous electroconductive material of the invention is used as the electrode material, a Graetzel type solar cell and a photomultiplier with excellent properties can be produced.

### BRIEF DESCRIPTION OF THE DRAWINGS

FIG. 1 schematically shows a device that can be used in forming a conductive oxide film using (i) a chemical vapor deposition method.

FIG. 2 schematically shows a device that can be used in forming a conductive oxide film using (iv) the method wherein highly reactive silanol groups present on the surface of the porous glass are reacted with an organic metal compound under high vacuum and the reaction product is then oxidized by heating in air (high-vacuum organic metal supporting method).

The following reference numerals indicate:
1. Electric furnace
2. Carrier gas/precursor
3. Carrier gas/water
4. Transport pipe for reactive gas
5. Glass reaction tube
6. Graphite screw
7. Controller for pressure reduction and pressure value
8. Discharge
9. Graphite seal
10. Porous glass
(1) Raw material chamber
(2) Reaction chamber
(3) Vacuum gauge
(4) Cold trap
(5) Vacuum pump
(6) Porous glass substrate
(7) valve

### BEST MODE FOR CARRYING OUT THE INVENTION

Examples are given below to describe the invention in more detail. However, the invention is not limited thereto.

In the following Examples, the surface resistivity was measured with a resistivity meter, Loresta-EP (MCP-T360, manufactured by Mitsubishi Chemical Corp.). The resistance between the outer surfaces was measured by a tester(MMH-930, product of Ferm). The light transmittance was measured by a spectrophotometer for ultraviolet and visible region (U-4100, product of Hitachi, Ltd.). The specific surface area was measured by mercury porosimetry using Micromeritics Aito Pore IV (product of Shimadzu Co.).

### EXAMPLE 1

### An Example for Forming a Conductive Oxide Film of SnO₂, Using (i) a Chemical Vapor Deposition Method

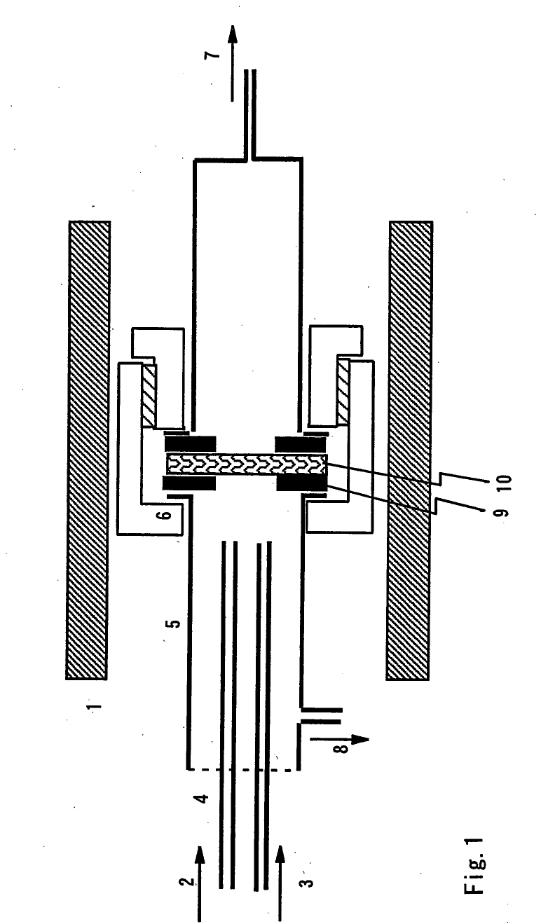

A porous glass plate having a thickness of 1 mm and a pore diameter of 50 nm (manufactured by Akagawa Hard Glass Co.,Ltd., specific surface area 36.3 m²/g) was heat-treated at 400° C. for 1 hour. A tin oxide film was then formed on the surfaces inside the pores in the porous glass using the device for the chemical vapor deposition method shown in FIG. 1. Tin tetrachloride (product of Wako Pure Chemical Industries, Ltd) was used as a raw material for the film. Water was used for the hydrolysis of tin tetrachloride. Argon and oxygen were used as the carrier gas for tin tetrachloride (product of Wako Pure Chemical Industries, Ltd) and water respectively. The argon flow rate was 10 ml/min, and the mole ratio of the tin tetrachloride relative to water was 1. The temperature of tin tetrachloride was adjusted with ice water. The porous glass plate was fixed with a graphite sheet as a seal material closely contacted to the forward end of a supporting glass tube in which internal pressure was reduced by a pump. The degree of vacuum was adjusted to 400 mm Hg by a controller. The distance between the porous glass plate and the gas outlet was 10 mm. The glass plate was heated to 400° C. and reaction was conducted for 5 hours. The glass plate thus treated on one side was turned over for conducting a reaction on the other side under the same conditions as before for 5 hours.

The pressure was brought to atmospheric pressure. A reaction was then carried out on both sides of the above-treated porous glass, for 1 hour on each side, to treat the outer surface of the glass plate. X-ray diffraction (XRD-600, product of Shimadzu Co.) confirmed that SnO₂ was produced on both sides of the treated porous glass plate.

In the obtained porous conductive material, the resistivity of the outer surface thereof was 6.5×10⁰ Ω·cm, and the resistance between two outer surfaces of the porous material was 300 kΩ. The light transmittance of visible light was 35% or more. The specific surface area was 20.5 m²/g.

### EXAMPLE 2

### An Example for Forming a Conductive Oxide Film of SnO₂ , Using (i) a Chemical Vapor Deposition Method

Reaction was conducted on both sides of the same kind of porous glass plate as used in Example 1, for 5 hours on each side, using the device shown in FIG. 1 under the same treatment conditions as in Example 1 with the exception of using a 3 to 5 wt % butanol solution of tin isobutoxide (containing a small amount of hydrochloric acid) as a precursor, to thereby form a film on the surfaces inside the pores.

The pressure was brought to atmospheric pressure. A reaction was then carried out on both sides of the above-treated porous glass plate, for 1 hour on each side, to form a film on the outer surface of the glass plate. X-ray diffraction confirmed that SnO₂ was produced on both sides of the treated porous glass plate.

In the obtained porous conductive material, the resistivity of the outer surface of the porous material was 5.7×10⁰ Ω·cm, and the resistance between the two outer surfaces thereof was 250 kΩ. The light transmittance of visible light was 35% or more. The specific surface area was 30.7 m²/g.

### EXAMPLE 3

### An Example for Forming a Conductive Oxide Film of F Doped SnO₂ Using (i) a Chemical Vapor Deposition Method

Reaction was conducted on both sides of the same kind of porous glass plate as used in Example 1, for 5 hours on each side, using the device shown in FIG. 1 at a pressure of 400 mm Hg under the same treatment conditions as in Example 1 with the exception of further adding a NH₄F vapor to allow F⁻ ions to diffuse into the SnO₂, whereby a film was formed on the surfaces inside the pores of the porous glass.

The pressure was brought to atmospheric pressure. A reaction was then carried out on both sides of the above-treated porous glass plate, for 1 hour on each side, to form a film on the outer surface of the glass plate.

X-ray diffraction confirmed that SnO₂ was produced on both sides of the treated porous glass plate.

In the obtained porous conductive material, the resistivity of the outer surface thereof was 7.3×10⁻¹ Ω·cm, and the resistance between the two outer surfaces of the porous material was 90 kΩ. The light transmittance of visible light was 35% or more. The specific surface area was 21.6 m²/g.

### EXAMPLE 4

### An Example for Forming a Conductive Oxide Film of Sb Doped SnO₂, Using (i)a Chemical Vapor Deposition Method

Reaction was conducted on both sides of the same kind of porous glass plate as used in Example 1, for 5 hours on each side, using the device shown in FIG. 1 at a pressure of 400 mm Hg under the same treatment conditions as in Example 1 with the exception of further adding a vapor obtained by heating antimony chloride (SbCl₅) at 120° C. to diffuse Sb⁵⁺ ions into the SnO₂, whereby a film was formed on the surfaces inside the pores of the porous glass.

The pressure was brought to atmospheric pressure. A reaction was then carried out on both sides of the above-treated porous glass plate, for 1 hour on each side, to form a film on the outer surface of the glass plate. X-ray diffraction measurement confirmed that SnO₂ was produced on both sides of the treated porous glass plate.

In the obtained porous conductive material, the resistivity of the outer surface thereof was 7.3×10⁻¹ Ω·cm, and the resistance between the two outer surfaces of the porous material was 90 kΩ. The light transmittance of visible light was 35% or more. The specific surface area was 21.6 m²/g.

### EXAMPLE 5

### An Example for Forming a Conductive Oxide Film of ITO, Using (i) a Chemical Vapor Deposition Method and (v) an Organic Template Method

Reaction was conducted on both sides of the same kind of porous glass plate as used in Example 1, for 5 hours on each side, using the device shown in FIG. 1 at a pressure of 400 mm Hg under the same treatment conditions as in Example with the exception of using indium chloride tetrahydrate and stannic chloride pentahydrate as a precursor, whereby a film was formed on the surfaces inside the pores of the porous glass.

The indium chloride tetrahydrate and stannic chloride pentahydrate were dissolved in polyethylene glycol 400 so that the final solid concentration of In₂O₃ and SnO₂ in a thin ITO film was 0.15 mol/l each. The solution was applied to the outer surfaces on both sides of the above treated porous glass plate by a spin coater at room temperature and was heated in air at 600° C. for 1 hour. An ITO film was formed by annealing at 500° C. in a helium stream for 1 hour. It was confirmed that ITO was produced on both sides of the treated porous glass plate.

In the obtained porous conductive material, the resistivity of the outer surface thereof was 3×10⁻¹ Ω·cm, and the resistance between the two outer surfaces of the porous material was 50 kΩ. The light transmittance of visible light was 35% or more. The specific surface area was 15.8 m²/g.

### EXAMPLE 6

### An Example for Forming a Conductive Oxide Film of ITO, Using (v) an Organic Template Method

The same kind of porous glass plate as used in Example 1 was immersed in a solution of indium chloride tetrahydrate and stannic chloride pentahydrate in polyethylene glycol 400. The reaction system thus obtained was reacted overnight under reduced pressure. After the porous glass plate was withdrawn from the solution, it was heated at 600° C. for 1 hour to form an ITO film on the surfaces inside the pores of the porous glass plate.

The above-mentioned solution was applied to the outer surface of the above-treated porous glass plate on both sides thereof by a spin coater at room temperature and was heated in air at 600° C. for 1 hour. An ITO film was formed by annealing at 500° C. in a helium stream for 1 hour. It was confirmed that an ITO film was produced on both sides of the treated porous glass plate.

In the obtained porous conductive material, the resistivity of the outer surface thereof was 2.8×10⁻¹ Ω·cm and the resistance between the two outer surfaces of the porous material was 170 kΩ. The light transmittance of visible light was 35% or more. The specific surface area was 28.1 m²/g.

### EXAMPLE 7

### An Example for Forming a Conductive Oxide Film of SnO₂, Using (iv) (High Vacuum Organic Metal Supporting Method) and (i) a Chemical Vapor Deposition Method

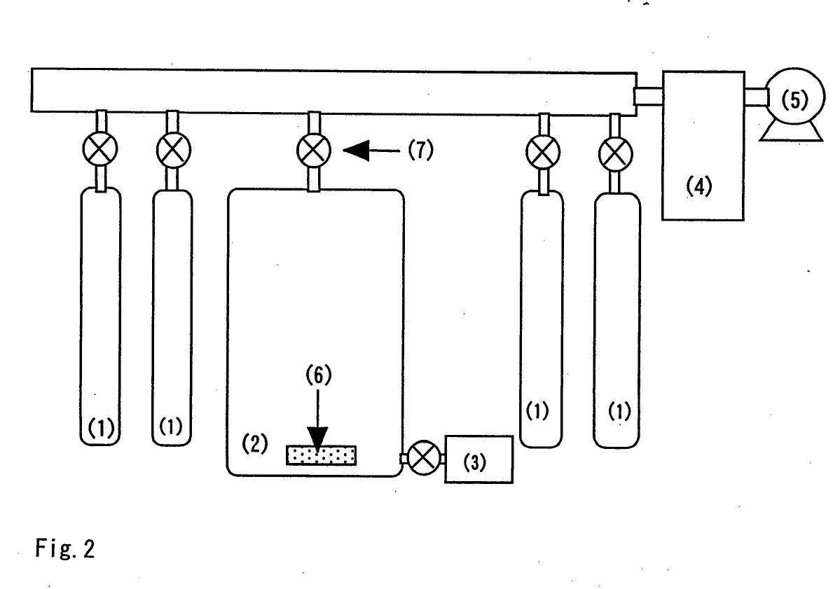

Using the device shown in FIG. 2, the same kind of porous glass plate as used in Example 1 was placed into a reaction chamber having a degree of vacuum of 10⁻⁴ torr, and a tin chloride vapor and water vapor were introduced into the chamber so that a conductive layer was formed on the surfaces inside the pores of the porous glass. After this treatment, the porous glass plate was heated in air at 400° C. for 1 hour.

Using the device shown in FIG. 1, a reaction was conducted at atmospheric pressure on both sides of the above-treated porous glass plate, for 1 hour on each side, to form a film on the outer surface thereof. It was confirmed that SnO₂ was produced on both sides of the treated porous glass plate.

In the obtained porous conductive material, the resistivity of the outer surface thereof was 8.5×10⁰ Ω·cm and the resistance between the two outer surfaces of the porous material was 200 kΩ. The light transmittance of visible light was 35% or more. The specific surface area was 30.5 m²/g.

### COMPARATIVE EXAMPLE 1

The same procedure as in Example 1 was repeated with exception of using a glass plate without pores in place of the porous glass plate in Example 1. That is, a reaction was carried out under the atmospheric pressure on both sides of the glass plate, for 5 hours on each side. The treated glass plate was confirmed to have SnO₂ produced on both sides.

In the obtained conductive material, the resistivity of the outer surface was 5.4×10⁻² Ω·cm, and the resistance between the two outer surfaces of the material was infinite. The light transmittance of visible light was 70% or more. The specific surface area was 3.5×10⁻⁴ m²/g.

### REFERENCE EXAMPLE

Graetzel type solar cells were produced using the porous conductive material of the invention or a conventional conductive film as the electrode material to make a comparison between their properties.
(1) Using tin tetrachloride as a raw material for a film as in Example 1, reaction was conducted in the same way as Example 1 on both sides of a porous glass plate, for 5 hours on each side, at a pressure of 400 mm Hg, whereby a SnO₂ film was formed on the surfaces inside the pores of the porous glass plate. Then, using titanium tetrachloride as a raw material for the film, reaction was conducted under the same conditions as in Example 1 on both sides of the obtained porous conductive plate, for 2 hours on each side, at a pressure of 400 mm Hg, whereby a TiO₂ film was formed on the surfaces inside the pores of the plate. Further, using tin tetrachloride as a raw material for the film, a reaction was conducted only on one side of the obtained plate for 1 hour at atmospheric pressure. The reacted side thus treated is referred to as electrode surface A and the other side is referred to as electrode surface B. A 0.1 M aqueous solution of titanium chloride was dropped onto surface B of the TiO₂ coated porous conductive material. After standing overnight, the porous material was washed with distilled water and dried, and it was then heated at 450° C. for 30 minutes. Thereafter it was cooled to 80° C. and immersed in an ethanol solution of a dye (RuL₂(SCN)₂, L=4,4′-dicarboxy-2,2′-bipyridine, concentration 3×10⁻⁴ M) overnight. The electrode withdrawn from the dye solution was immersed in an acetonitrile solution containing 2 mole % of t-butylpyridine for 15 minutes. Thereafter the electrode was washed with an acetonitrile solution and dried. A few drops of an iodine-containing electrolyte solution (30 mM iodine and 0.3M potassium iodide dissolved in acetonitrile) were dropped on the electrode surface B. The obtained electrode was covered with a counter electrode coated with platinum paste to give a solar cell. The cell is referred to as cell A.
(2) A mixed solution of 125 ml of titanium isopropoxide and 750 ml of an 0.1 M aqueous solution of nitric acid was stirred at 80° C. for 8 hours. A hydrothermal treatment was then conducted at 230° C. for 12 hours. TiO₂ was adjusted to 11 wt % by concentration. Polyethylene glycol (PEG, molecular weight 20000) was added to the solution in amount of 5 wt %, finally giving 10.5 wt % sol of TiO₂(e.g., Chrostphe J Barbe, et al., J. Am. Ceram. Soc., 80 (12) 3157-71 (1997)). The sol was applied to one side of the conductive film formed by the method described in Comparative Example 1 using a doctor blade method, and the film was then heated at 450° C. in the ambient atmosphere for 30 minutes. The product was treated with an aqueous solution of titanium tetrachloride and dyes were supported on the product by the same method as in preparation of the cell A. A solar cell was produced from thus obtained product, an electrolyte and a counter electrode. The cell is referred to as cell B.
(3) The cells A and B were investigated with regarded to their properties concerning the conversion efficiency of light energy. The conversion efficiency of light energy was measured by irradiation with artificial solar beams (AM1.5, 100 mW/cm²) using a solar simulator (spectrometer). Cell B prepared by use of the conductive film of Comparative Example 1 showed 4% as the Photons-to-Current conversion efficiency of light energy (the number of electrons produced by conversion when 100 photons incident on the solar cell), whereas cell A prepared by use of the porous conductive material of the invention showed 8% as the Photons-to-Current conversion efficiency, i.e. twice the value.
   Industrial Applicability of the Invention

The porous conductive material of the invention has light transmitting and electroconductive properties and, by adjusting the pore diameter, can have a surface area increased 1,000 to 100,000 folds. Electric current can pass between the two surfaces of the porous material since the conductive film is applied to the surfaces inside the pores thereof. Further, the porous material can be produced in any form. In addition, the porous material can be provided with properties of typical inorganic films such as weathering resistance, heat resistance and the like.

As set forth above, the porous conductive material of the invention has excellent properties: (i) electric current can pass between the two surfaces of the material because a conductive film is applied to the surface inside the pores of the porous material; and (ii) the porous conductive material of the invention has a far greater specific surface area than conductive films lacking pores.

Because of these features, the following advantages are realized, for example. When the porous conductive material of the invention is used as the material for electrodes in a Graetzel type solar cell, the surface area can be increased to several thousands or more times, so that there is provided a solar cell capable of converting a light energy to an electrical energy with high efficiency. Further, when the porous conductive material of the invention is used as the electrode material in a photomultiplier, the probability of photons colliding with the Photons-to-Current conversion material is markedly increased, so that the porous conductive material used can provide a photomultiplier which gives signals at least dozens of times as large as the signals emitted by the multipliers of a type permitting photons to pass therethrough.

As described above, the porous conductive material of the invention has various advantageous properties. In consequence, when the porous conductive material of the invention is employed as an electrode material, highly efficient Graetzel type solar cells and photomultipliers can be provided, i.e., superior effects can be accomplished with devices in the electricity/electronics field.

1. A light transmitting porous conductive material comprising a porous glass and a conductive oxide film formed on the outer surfaces of the porous glass and on the surfaces inside the pores thereof.

2. The porous conductive material according to claim 1, wherein the resistivity of an outer surface of the porous conductive material is 10⁻⁴ to 10⁴ Ω·cm, the resistance between the two outer surfaces of the porous conductive material is 10⁻⁴ k to 500 kΩ, and the specific surface area of the porous conductive material is 4 to 600 m²/g.

3. The porous conductive material according to claim 2, wherein the resistivity of an outer surface of the porous conductive material is 10⁻⁴ to 10¹ Ω·cm, the resistance between the two outer surfaces of the porous conductive material is 10⁻⁴ k to 300 kΩ, and the specific surface area of the porous conductive material is 9 to 400 m²/g.

4. The porous conductive material according to claim 1, wherein the conductive oxide film is constituted by at least one conductive oxids selected from the group consisting of SnO₂, In₂O₃, ITO (Sn doped In₂O₃), ZnO, PbO₂, ZnSb₂O₆, CdO, CdIn₂O₄, MgIn₂O₄, ZnGa₂O₄, CdGa₂O₄, Cd₂SnO₄, Zn₂SnO₄, Tl₂O₃, TIOF, Ga₂O₃, GaInO₃, Cd₂SnO₄, CdSnO₃, In₂TeO₆, InGaMgO₄, InGaZnO₄, Zn₂In₂O₅, AgSbO₃, Cd₂GeO₄, Cd₂Ge₂O₇, ZnSnO₃, AgInO₂, CuAlO₂, CuGaO₂, SrCu₂O₂, amorphous In₂O₃, amorphous CdO—GeO₂, Sb doped SnO₂, F doped SnO₂, In doped ZnO, Ga doped ZnO and Al doped ZnO.

5. The porous conductive material according to claim 4, wherein the conductive oxide film is constituted by at least one conductive oxide selected from the group consisting of SnO₂, In₂O₃, ITO, Sb doped SnO₂ and F doped SnO₂.

6. A Graetzel type solar cell comprising the porous conductive material according to any one of claims 1 to 5 as an electrode material.

7. A photomultiplier comprising the porous conductive material according to any one of claims 1 to 5 as an electrode material.

8. A method for preparing a light transmitting porous conductive material comprising the steps of: (1) forming a conductive oxide film on the surfaces inside the pores of a porous glass, and (2) forming a conductive oxide film on the outer surfaces of the porous glass.

9. The method according to claim 8, wherein any method selected from the group consisting of the following methods (i) to (v) is employed in the step (1) of forming a conductive oxide film on the surfaces inside the pores of the porous glass:(i) a chemical vapor deposition method, (ii) a sputtering method, (iii) an impregnation method, (iv) a method wherein silanol groups present on the surface of the porous glass are reacted with an organic metal compound under high vacuum and the reaction product is then oxidized by heating in air, and (v) a method wherein a mixture of a polymer or an amine group-containing organic metal compound with a raw material for the film is applied to the surface of the porous glass and then the polymer or the organic compound is removed by heating in air.

10. The method according to claim 8, wherein any method selected from the group consisting of the following methods (i), (ii) and (v) is employed in the step (2) of forming a conductive oxide film on the outer surfaces of the porous glass: (i) a chemical vapor deposition method, (ii) a sputtering method, and (v) a method wherein a mixture of a polymer or an amine group-containing organic metal compound with a raw material for the film is applied to the surface of the porous glass and then the polymer or the organic compound is removed by heating in air.

11. The method according to claim 8, wherein any method selected from the group consisting of the following methods (i), (iv) and (v) is employed in the step (1) of forming a conductive oxide film on the surfaces inside the pores of the porous glass:(i) a chemical vapor deposition method, (iv) a method wherein silanol groups present on the surface of the porous glass are reacted with an organic metal compound under high vacuum and the reaction product is then oxidized by heating in air, and (v) a method wherein a mixture of a polymer or an amine group-containing organic metal compound with a raw material for the film is applied to the surface of the porous glass and then the polymer or the organic compound is removed by heating in air, and wherein the method (i) or (v) is employed in the step (2) of forming a conductive oxide film on the outer surfaces of the porous glass:(i) a chemical vapor deposition method, or (v) a method wherein a mixture of a polymer or an amine group-containing organic metal compound with a raw material for the film is applied to the surface of the porous glass and then the polymer or the organic compound is removed by heating in air.
